(19) United States
(12) Patent Application Publication
(10) Pub. No.: US 2022/0393432 A1
(43) Pub. Date: Dec. 8, 2022

(54) BRAGG GRATING AND METHOD FOR MANUFACTURING THE SAME AND DISTRIBUTED FEEDBACK LASER DEVICE

(71) Applicant: Xiamen San'an Integrated Circuit Co., Ltd., Xiamen (CN)

(72) Inventors: Weizhong SUN, Xiamen (CN); Sangzhi ZHAO, Xiamen (CN); Xun LI, Xiamen (CN)

(21) Appl. No.: 17/888,066

(22) Filed: Aug. 15, 2022

Related U.S. Application Data
(63) Continuation-in-part of application No. PCT/CN2021/105142, filed on Jul. 8, 2021.

(30) Foreign Application Priority Data
Jul. 21, 2020 (CN) 202010707847.9

(51) Int. Cl. H01S 5/12; H01S 5/30; H01S 5/22

(52) U.S. Cl. CPC H01S 5/1228; H01S 5/305; H01S 5/2202

(57) ABSTRACT

A Bragg grating includes a lower waveguide layer, a middle waveguide layer disposed on the lower waveguide layer, an upper waveguide structure disposed on the middle waveguide layer opposite to the lower waveguide layer, and a buried layer. The upper waveguide structure includes upper waveguide elements that are arranged on a surface of the middle waveguide layer, and that are spaced apart from one another by cavities. The buried layer fills the cavity. The middle waveguide layer has a refractive index lower than that of each of the lower waveguide layer and the upper waveguide elements. The lower waveguide layer has a doping type the same as that of the middle waveguide layer. A method for manufacturing the Bragg grating is also provided.

### CROSS-REFERENCE TO RELATED APPLICATION

This application is a bypass continuation-in-part application of PCT International Application No. PCT/CN2021/105142 filed on Jul. 8, 2021, which claims priority of Chinese Invention Patent Application No. 202010707847.9 filed on Jul. 21, 2020. The entire content of each of the International and Chinese patent application is incorporated herein by reference.

### FIELD

The disclosure relates to a semiconductor laser device, and more particularly to a Bragg grating and a method for manufacturing the same and a distributed feedback laser device.

### BACKGROUND

With development of data centers and optical fiber access network, a demand for a communication system having a low cost and a high bit rate is gradually increasing. In order to reduce cost, a directly modulated semiconductor laser device (e.g., a distributed feedback laser device) is generally used as a light source in such communication system instead of an external modulator, so as to avoid structural complexity and additional expense.

In a conventional distributed feedback laser device, a coupling coefficient of a common grating would decrease with an increased injection current (according to Kramers-Kronig relations, compared with a wide bandgap material, a refractive index of a narrow bandgap material may be relatively reduced when current carriers flow therethrough), and an effective refractive index difference of the grating in proportional to the coupling coefficient thereof would also decrease. Due to the decrease in the coupling coefficient of the grating, a distributed feedback of an optical cavity of the conventional distributed feedback laser device might be reduced, resulting in a large cavity loss thereof. A differential value of such large cavity loss is positive and a lower differential gain is obtained, so that the conventional distributed feedback laser device has a decreased relaxation oscillation frequency and a narrow bandwidth of a small signal modulation response, which is not conducive for high-speed direct modulation.

### SUMMARY

An object of the disclosure is to provide a Bragg grating, a method for manufacturing the same and a distributed feedback laser device including the same, which can alleviate or overcome the aforesaid shortcomings of the prior art.

According to a first aspect of the disclosure, a Bragg grating adapted for use in a distributed feedback laser device includes a lower waveguide layer, a middle waveguide layer, an upper waveguide structure, and a buried layer.

The middle waveguide layer is disposed on the lower waveguide layer in a laminating direction.

The upper waveguide structure is disposed on the middle waveguide layer opposite to the lower waveguide layer, and includes a plurality of upper waveguide elements that are arranged on a surface of the middle waveguide layer in a direction perpendicular to the laminating direction, and that are spaced apart from one another by cavities.

The buried layer fills the cavity.

The middle waveguide layer has a refractive index that is lower than that of each of the lower waveguide layer and the upper waveguide elements.

The lower waveguide layer has a doping type the same as that of the middle waveguide layer.

Each of the upper waveguide elements has a doping type opposite to that of the middle waveguide layer.

According to a second aspect of the disclosure, a distributed feedback laser device includes the abovementioned Bragg grating.

According to a third aspect of the disclosure, a method for manufacturing a Bragg grating includes the steps of:

a) forming a lower waveguide layer;

b) forming a middle waveguide layer on the lower waveguide layer in a laminating direction;

c) forming an upper waveguide layer on the middle waveguide layer opposite to the lower waveguide layer in the laminating direction, the middle waveguide layer having a refractive index that is lower than that of each of the lower waveguide layer and the upper waveguide layer, the lower waveguide layer having a doping type the same as that of the middle waveguide layer, the upper waveguide layer having a doping type opposite to that of the middle waveguide layer;

d) patterning the upper waveguide layer, so as to form a plurality of upper waveguide elements that are arranged on a surface of the middle waveguide layer in a direction perpendicular to the laminating direction and that are spaced apart from one another by cavities; and

e) forming a buried layer to fill the cavity.

### BRIEF DESCRIPTION OF THE DRAWINGS

Other features and advantages of the disclosure will become apparent in the following detailed description of the embodiment(s) with reference to the accompanying drawings, in which:

FIGS. 1 and 2 are schematic views illustrating a first embodiment of a Bragg grating according to the disclosure;

FIG. 3 is a graph illustrating relationship of effective refractive index difference and coupling coefficient in a grating;

FIG. 4 is a graph illustrating relationship of coupling coefficient and cavity loss in a grating;

FIG. 5 is a graph illustrating relationship of differential cavity loss and relaxation oscillation frequency;

FIG. 6 is a schematic view illustrating a second embodiment of the Bragg grating according to the disclosure; and

FIG. 7 is a schematic view illustrating an embodiment of a distributed feedback laser device according to the disclosure;

FIG. 8 is a schematic view illustrating an embodiment of the distributed feedback laser device according to the disclosure; and

FIG. 9 is a flow chart illustrating the consecutive steps of a method for manufacturing the first embodiment of the Bragg grating.

### DETAILED DESCRIPTION

Before the disclosure is described in greater detail, it should be noted that where considered appropriate, reference numerals have been repeated among the figures to indicate corresponding or analogous elements, which may optionally have similar characteristics.

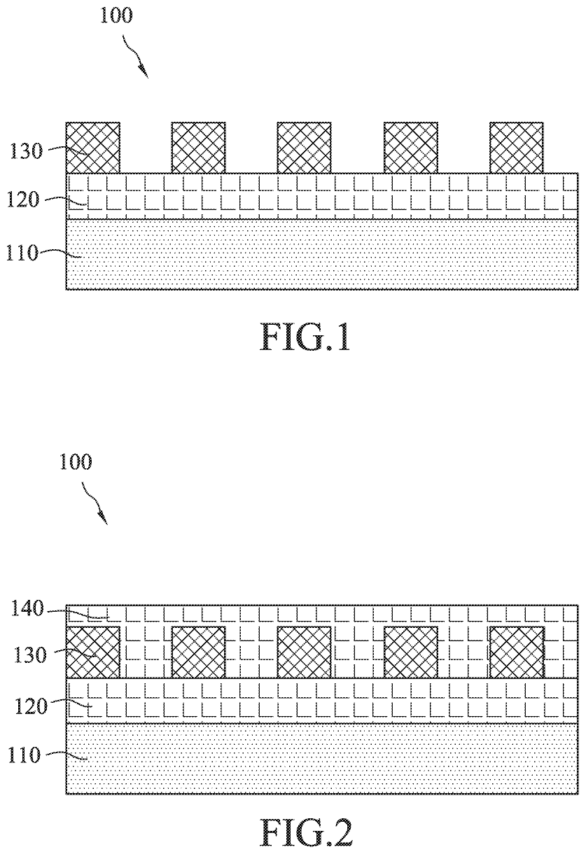

Referring to FIGS. 1 and 2, a first embodiment of a Bragg grating 100 according to the present disclosure includes a lower waveguide layer 110, a middle waveguide layer 120, an upper waveguide structure, and a buried layer 140. The Bragg grating 100 is adapted for use in a distributed feedback laser device.

The middle waveguide layer 120 is disposed on the lower waveguide layer 110 in a laminating direction.

The upper waveguide structure is disposed on the middle waveguide layer 120 opposite to the lower waveguide layer 110, and includes a plurality of upper waveguide elements 130 that are arranged on a surface of the middle waveguide layer 120 in a direction perpendicular to the laminating direction, and that are spaced apart from one another by cavities. The upper waveguide elements 130 may be periodically arranged on the surface of the middle waveguide layer 120. In certain embodiments, the upper waveguide elements 130 are arranged on the surface of the middle waveguide layer 120 along a cavity direction of the distributed feedback laser device (i.e., a propagating direction of light). The middle waveguide layer 120 has a refractive index that is lower than that of each of the lower waveguide layer 110 and the upper waveguide elements 130. The lower waveguide layer 110 has a doping type the same as that of the middle waveguide layer 120. Each of the upper waveguide elements 130 has a doping type opposite to that of the middle waveguide layer 120, so as to form a reverse biased PN junction.

The buried layer 140 fills the cavities, is disposed on the upper waveguide elements 130 and has a flat surface (see FIG. 2). In certain embodiments, the buried layer 140 may only fill the cavities.

In certain embodiments, the refractive index of each of the upper waveguide elements 130 is greater than that of the lower waveguide layer 110. In alternative embodiments, the refractive index of the lower waveguide layer 110 is greater than that of each of the upper waveguide elements 130. There are no particular limitations on a range of the refractive index of each of the upper waveguide elements 130, the middle waveguide layer 120 and the lower waveguide layer 110, as long as the refractive index of the middle waveguide layer 120 is lower than that of each of the lower waveguide layer 110 and the upper waveguide elements 130, and the refractive indices of the upper waveguide elements 130, the middle waveguide layer 120 and the lower waveguide layer 110 are different.

In general, in order to allow the refractive index of the lower waveguide layer 110 of the Bragg grating 100 to be significantly changed with injected current carriers, the lower waveguide layer 110 may be made of a material that has a refractive index relatively sensitive to a change in a concentration of the injected current carriers.

In certain embodiments, in practical application, the middle waveguide layer 120 may be made of a material that has an etching selectivity greater than that of the upper waveguide elements 130, which enables the cavities to be formed to penetrate the upper waveguide layer and terminate at the middle waveguide layer 120 during a patterning process (including an etching step) for forming the upper waveguide elements 130 (which will be described hereinafter). As such, a damage of the lower waveguide layer 110 caused by overetching can be avoided, and the refractive index change of the lower waveguide layer 110 in accordance to the concentration of the injected current carriers may not be adversely affected.

The middle waveguide layer 120 may have a thickness ranging from 10 nm to 50 nm, such as 10 nm, 20 nm, 25 nm, 30 nm, 35 nm, and 50 nm. By having the middle waveguide layer 120 with the abovementioned thickness range, the injected current carriers passing through the cavities (regarded as relatively low refractive index regions) can be prevented from being laterally diffused to upper waveguide elements 130 (regarded as relatively high refractive index regions), and the damage of the lower waveguide layer 110 caused by overetching can be avoided during the etching process for forming the upper waveguide elements 130.

There are no particular limitations on a material for forming each of the lower waveguide layer 110, the upper waveguide elements 130, and the middle waveguide layer 120. In certain embodiments, each of the lower waveguide layer 110 and the upper waveguide elements 130 may be made of indium gallium arsenide phosphide, and the middle waveguide layer 120 may be made of indium phosphide.

In this embodiment, as shown in FIG. 2, the buried layer 140 is formed on the upper waveguide elements 130 and fills the cavities.

There are no particular limitations on a material and a doping type for the buried layer 140. In certain embodiments, the buried layer 140 and the middle waveguide layer 120 may be made of a same material and may have a same doping type. In such case, the doping type of each of the upper waveguide elements 130 is opposite to that of each of the middle waveguide layer 120 and the buried layer 140.

In certain embodiments, the buried layer 140 is not doped, and in such case, the doping type of each of the upper waveguide elements 130 is only opposite to that of the middle waveguide layer 120.

In certain embodiments, the buried layer 140 may be made of indium phosphide.

In certain embodiments, the buried layer 140 may only fill the cavities and is not disposed on the upper waveguide elements 130, and may have a refractive index lower than that of the upper waveguide elements 130, so as to avoid an effective refractive index of the buried layer 140 (regarded as the relatively low refractive index regions) being greater than that of the upper waveguide elements 130.

By having the upper waveguide elements 130 that are spaced apart from one another by the cavities, the effective refractive index of the buried layer 140 is lower than that of the upper waveguide elements 130. The buried layer 140 may be regarded as a relatively low refractive index region and each of the upper waveguide elements 130 may be regarded as a relatively high refractive index region. As such, the Bragg grating 100 has the relatively high refractive index regions and the relatively low refractive index regions that are periodically disposed by one another along the cavity direction of the distributed feedback laser device.

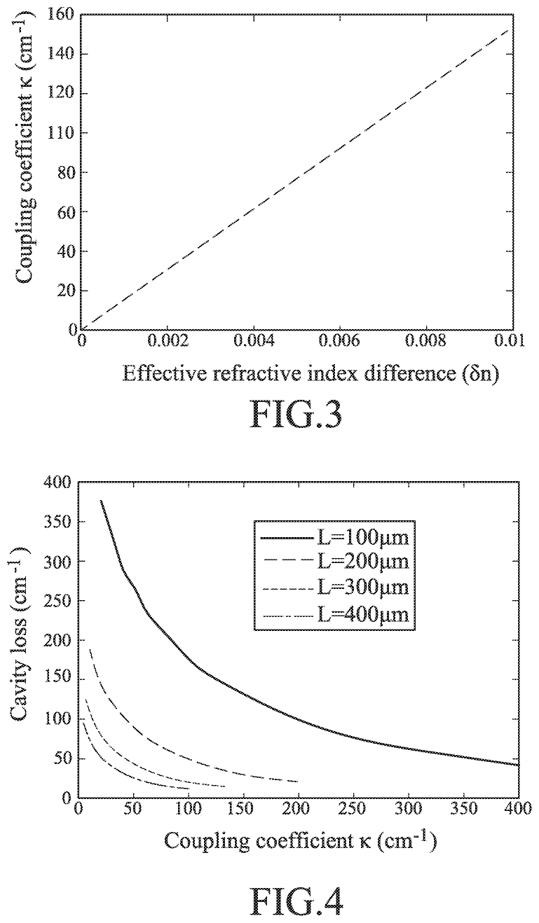

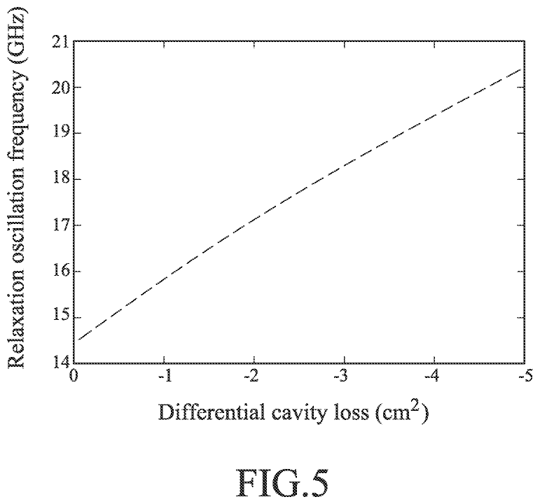

When the distributed feedback laser device is in a forward biased state, the reverse biased PN junction formed between the layer of the distributed feedback laser device and the upper waveguide elements 130 (i.e., the relatively high refractive index regions) can prevent the flow of injected current carriers, so that the refractive index of the upper waveguide elements 130 may not significantly change with a current change of the distributed feedback laser device, and the injected current carriers can pass through the buried layer 140 (i.e., the relatively low refractive index regions), so that the refractive index thereof may be decreased with an increased current of the distributed feedback laser device. In such case, with the increased current of the distributed feedback laser device, an effective refractive index difference between the relatively high refractive index regions and the relatively low refractive index regions may be increased. FIG. 3 illustrates that the coupling coefficient of a grating is proportional to the effective refractive index difference thereof. Accordingly, the coupling coefficient of the Bragg grating 100 increases with an increased current of the distributed feedback laser device. FIG. 4 illustrates a cavity loss of the distributed feedback laser device decreases with an increased coupling coefficient of the grating (e.g., the Bragg grating 100). Accordingly, the cavity loss of the distributed feedback laser device decreases with an increased current. As such, with the increased current, a negative value of differential cavity loss of the distributed feedback laser device is obtained and a differential gain thereof significantly increases, so that the distributed feedback laser device has an increased relaxation oscillation frequency (according to a dynamic model of a semiconductor laser device, see FIG. 5) and a wide bandwidth of a small signal modulation response, thereby enabling the distributed feedback laser device to have a high-speed direct modulation.

In practical application, according to a location of the Bragg grating 100 in the distributed feedback laser device, the lower waveguide layer 110, the upper waveguide elements 130, and the middle waveguide layer 120 may have different doping types.

In certain embodiments, when the Bragg grating 100 is to be disposed at a P-side of the distributed feedback laser device, the doping type of each of the lower waveguide layer 110 and the middle waveguide layer 120 is P-type, and the doping type of each of the upper waveguide elements 130 is N-type.

In certain embodiments, when the Bragg grating 100 is to be disposed at an N-side of the distributed feedback laser device, the doping type of each of the lower waveguide layer 110 and the middle waveguide layer 120 is N-type, and the doping type of each of the upper waveguide elements 130 is P-type.

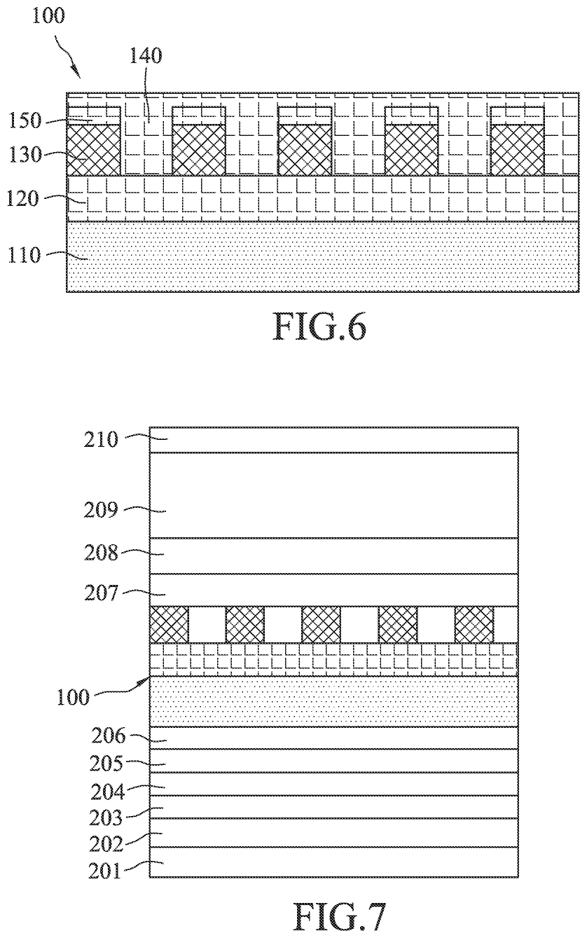

Referring to FIG. 6, a second embodiment of the Bragg grating 100 according to the present disclosure is generally similar to the first embodiment, except that, in the second embodiment, the Bragg grating 100 further includes a plurality of interposed layers 150, each of which is disposed between the buried layer 140 and a corresponding one of the upper waveguide elements 130. The interposed layers 150 and the buried layer 140 may be made of a same material. By having the interposed layers 150, lattice mismatch and thermal mismatch between the buried layer 140 and the upper waveguide elements 130 can be reduced, which is conducive for an epitaxial growth of the buried layer 140. In addition, the interposed layers 150 may protect the upper waveguide elements 130 from being damaged.

This disclosure also provides the distributed feedback laser device including the abovementioned Bragg grating 100.

In certain embodiments, the distributed feedback laser device is a laser device that has a communication wavelength and that is made of an aluminum gallium indium arsenide (AlGaInAs)-indium gallium arsenide phosphide (InGaAsP)/indium phosphide (InP)-based material.

The distributed feedback laser device may further include a N-type substrate 201, and a N-type buffer layer 202, a lower confinement layer 203, an active layer 204, an upper confinement layer 205, an isolating layer 206, a P-type isolating layer 207, a P-type etch stop layer 208, a P-type cladding layer 209 and a P-type top covering layer 210 that are disposed on the substrate 201 in such order. For example, as shown in FIG. 7, when the Bragg grating 100 is to be disposed at the P-side of the distributed feedback laser device, the Bragg grating 100 is disposed between the isolating layer 206 and the P-type isolating layer 207, the upper waveguide elements 130 are distal from the N-type substrate 201, and the doping type of the upper waveguide elements 130 is N-type. In certain embodiments, the P-type isolating layer 207 may have a doping concentration ranging from 1×10¹⁷/cm³ to 3×10¹⁷/cm³.

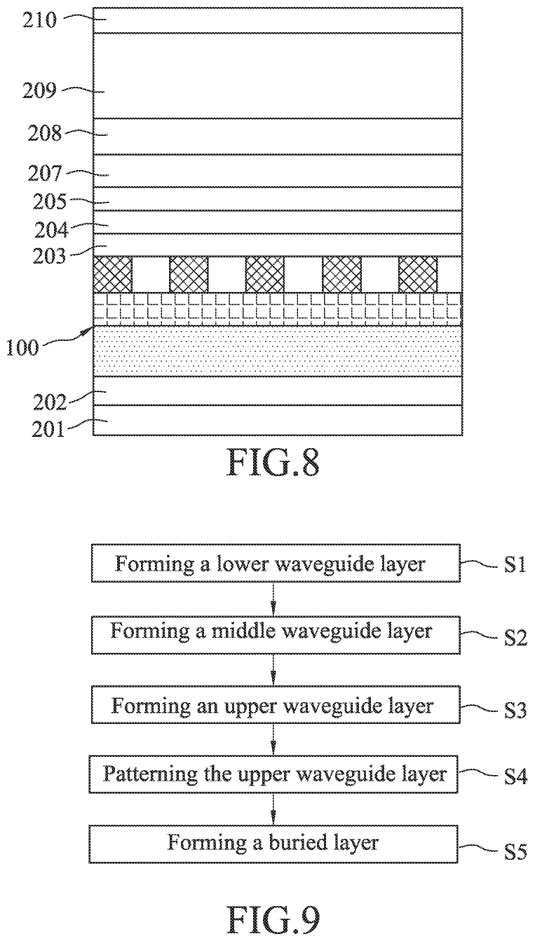

For another example, as shown in FIG. 8, when the Bragg grating 100 is to be disposed at the N-side of the distributed feedback laser device, the Bragg grating 100 is disposed between the N-type buffer layer 202 and the lower confinement layer 203, the upper waveguide elements 130 are distal from the N-type substrate 201, and the doping type of the upper waveguide elements 130 is P-type.

Each of the N-type substrate 201, the N-type buffer layer 202, the P-type isolating layer 207, and the cladding layer 209 may be made of indium phosphide.

Each of the lower confinement layer 203, the active layer 204, and the upper confinement layer 205 may be made of aluminum gallium indium arsenide. The P-type etch stop layer 208 may be made of indium gallium arsenide phosphide. The top covering layer 210 may be made of indium gallium arsenide.

Referring to FIG. 9, this disclosure also provides a method for manufacturing the first embodiment of the Bragg grating 100, which includes the following consecutive steps S1 to S5.

In step S1, the lower waveguide layer 110 is formed.

In step S2, the middle waveguide layer 120 is formed on the lower waveguide layer 110 in the laminating direction.

In step S3, an upper waveguide layer is formed on the middle waveguide layer 120 opposite to the lower waveguide layer 110 in the laminating direction. The upper waveguide layer has a doping type opposite to that of the middle waveguide layer 120.

In step S4, the upper waveguide layer is patterned, so as to form the upper waveguide elements 130.

In step S5, the buried layer 140 is formed to fill the cavities. After formation of the buried layer 140, the Bragg grating 100 is obtained.

Each of the lower waveguide layer 110, the middle waveguide layer 120, and the upper waveguide layer may be formed using an epitaxial growth technique, such as chemical vapor deposition (CVD) (e.g., metal organic chemical vapor deposition (MOCVD), molecular beam epitaxy (MBE), and hydride vapor phase epitaxy (HVPE).

Moreover, in certain embodiments, each of the lower waveguide layer 110, the middle waveguide layer 120, and the upper waveguide elements 130 may be doped by directly introducing a corresponding type of an impurity source to a gas used in an epitaxial growth process. In alternative embodiments, after the lower waveguide layer 110, the middle waveguide layer 120, and the upper waveguide layer are sequentially formed, each of the lower waveguide layer 110, the middle waveguide layer 120, and the upper waveguide layer may be doped with a corresponding type of an impurity by ion implantation or diffusion. For example, because the lower waveguide layer 110 and the middle waveguide layer 120 have the same doping type and are adjacent to each other, the lower waveguide layer 110 and the middle waveguide layer 120 can be sequentially formed followed by doping with the corresponding type of the impurity by ion implantation or diffusion.

In step S4, the upper waveguide layer may be patterned using a selective etching technique, such as a dry etching, a wet etching or a combination thereof. In certain embodiments, the upper waveguide layer may be selectively etched by one of inductively coupled plasma (ICP) etching, reactive ion etching (RIE), downstream plasma etching and direct plasma etching in a plasma etching machine. In addition, by adjusting etching process parameters, the cavity can penetrate the upper waveguide layer and terminate at the middle waveguide layer 120.

In certain embodiments, after formation of the upper waveguide layer and before patterning of the upper waveguide layer, an interposed material layer can be formed on the upper waveguide layer opposite to the middle waveguide layer 120. Afterwards, the interposed material layer and the upper waveguide layer can be patterned simultaneously, so as to form the interposed layers 150 and the upper waveguide elements 130. Then, step S5 is performed. In certain embodiments, after formation of the buried layer 140, the Bragg grating 100 may be subjected to a planarization treatment. The formation of the interposed layers 150 is conducive for protecting the upper waveguide elements 130 and an epitaxial growth of the buried layer 140.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A Bragg grating adapted for use in a distributed feedback laser device, comprising:
a lower waveguide layer;
a middle waveguide layer disposed on said lower waveguide layer in a laminating direction;
an upper waveguide structure disposed on said middle waveguide layer opposite to said lower waveguide layer, and including a plurality of upper waveguide elements that are arranged on a surface of said middle waveguide layer in a direction perpendicular to the laminating direction, and that are spaced apart from one another by cavities; and
a buried layer filling said cavity,
wherein
said middle waveguide layer has a refractive index lower than that of each of said lower waveguide layer and said upper waveguide elements,
said lower waveguide layer has a doping type the same as that of said middle waveguide layer, and
each of said upper waveguide elements has a doping type opposite to that of said middle waveguide layer.

2. The Bragg grating of claim 1, wherein said upper waveguide elements are periodically arranged on said middle waveguide layer.

3. The Bragg grating of claim 1, wherein when said Bragg grating is to be disposed at a P-side of said distributed feedback laser device, said doping type of each of said lower waveguide layer and said middle waveguide layer is P-type, and said doping type of each of said upper waveguide elements is N-type.

4. The Bragg grating of claim 1, wherein when said Bragg grating is to be disposed at an N-side of said distributed feedback laser device, said doping type of each of said lower waveguide layer and said middle waveguide layer is N-type, and said doping type of each of said upper waveguide elements is P-type.

5. The Bragg grating of claim 1, wherein said buried layer and said middle waveguide layer are made of a same material, and have the same doping type.

6. The Bragg grating of claim 1, further comprising a plurality of interposed layers, each of which is disposed between said buried layer and a corresponding one of said upper waveguide elements.

7. The Bragg grating of claim 6, wherein said interposed layers and said buried layer are made of a same material.

8. The Bragg grating of claim 1, wherein each of said lower waveguide layer and said upper waveguide elements are made of indium gallium arsenide phosphide, and said middle waveguide layer is made of indium phosphide.

9. A distributed feedback laser device, comprising the Bragg grating as claimed in claim 1.

10. The distributed feedback laser device of claim 9, further comprising an N-type substrate, an N-type buffer layer, a lower confinement layer, an active layer, an upper confinement layer, an isolating layer, a P-type isolating layer, a P-type etch stop layer, a P-type cladding layer and a P-type top covering layer that are disposed on said substrate in such order, said Bragg grating being disposed between said N-type isolating layer and said P-type isolating layer, said upper waveguide elements being distal from said substrate, said doping type of said upper waveguide elements being N-type.

11. The distributed feedback laser device of claim 9, further comprising an N-type substrate, an N-type buffer layer, a lower confinement layer, an active layer, an upper confinement layer, an isolating layer, a P-type isolating layer, a P-type etch stop layer, a P-type cladding layer and a P-type top covering layer that are disposed on said substrate in such order, said Bragg grating being disposed between said buffer layer and said lower confinement layer, said upper waveguide elements being distal from said substrate, said doping type of said upper waveguide elements being P-type.

12. The distributed feedback laser device of claim 9, wherein when said Bragg grating is to be disposed at a P-side of said distributed feedback laser device, said doping type of each of said lower waveguide layer and said middle waveguide layer is P-type, and said doping type of each of said upper waveguide elements is N-type.

13. The distributed feedback laser device of claim 9, wherein when said Bragg grating is to be disposed at an N-side of said distributed feedback laser device, said doping type of each of said lower waveguide layer and said middle waveguide layer is N-type, and said doping type of each of said upper waveguide elements is P-type.

14. A method for manufacturing a Bragg grating, comprising the steps of:
forming a lower waveguide layer;
forming a middle waveguide layer on the lower waveguide layer in a laminating direction;
forming an upper waveguide layer on the middle waveguide layer opposite to the lower waveguide layer in the laminating direction, the middle waveguide layer having a refractive index lower than that of each of the lower waveguide layer and the upper waveguide layer, the lower waveguide layer having a doping type the same as that of the middle waveguide layer, the upper waveguide layer having a doping type opposite to that of the middle waveguide layer;
patterning the upper waveguide layer, so as to form a plurality of upper waveguide elements that are arranged on a surface of the middle waveguide layer in a direction perpendicular to the laminating direction and that are spaced apart from one another by cavities; and
forming a buried layer to fill the cavity.

15. The method of claim 14, wherein the upper waveguide elements are periodically arranged on the middle waveguide layer.

16. The method of claim 14, wherein the buried layer and the middle waveguide layer are made of a same material.

17. The method of claim 14, wherein the buried layer has a doping type the same as that of the middle waveguide layer.

18. The method of claim 14, wherein each of the lower waveguide layer and the upper waveguide elements are made of indium gallium arsenide phosphide, and the middle waveguide layer is made of indium phosphide.

19. The method of claim 14, wherein the Bragg grating is adapted for use in a distributed feedback laser device, and when the Bragg grating is to be disposed at a P-side of the distributed feedback laser device, the doping type of each of the lower waveguide layer and the middle waveguide layer is P-type, and the doping type of each of the upper waveguide elements is N-type.

20. The method of claim 14, wherein the Bragg grating is adapted for use in a distributed feedback laser device, and when the Bragg grating is to be disposed at an N-side of the distributed feedback laser device, the doping type of each of the lower waveguide layer and the middle waveguide layer is N-type, and the doping type of each of the upper waveguide elements is P-type.
